(19) United States
(12) Patent Application Publication
(10) Pub. No.: US 2020/0144429 A1
(43) Pub. Date: May 7, 2020

(54) Plasmonic Multiple Exciton Generation

(71) Applicants: Michael J. Naughton, Chestnut Hill, MA (US); Krzysztof Kempa, Chestnut Hill, MA (US)

(72) Inventors: Michael J. Naughton, Chestnut Hill, MA (US); Krzysztof Kempa, Chestnut Hill, MA (US)

(73) Assignee: The Trustees of Boston College, Chestnut Hill, MA (US)

(21) Appl. No.: 16/177,515

(22) Filed: Nov. 1, 2018

(51) Int. Cl. H01L 31/0352; H01L 31/0224; H01L 31/06

(52) U.S. Cl. CPC H01L 31/035272; H01L 31/06; H01L 31/022425

(57) ABSTRACT

Structures and methods for electron-hole photogeneration by plasmonic multiple exciton generation in light absorbing layers and solar cells are disclosed.

### FIELD

The embodiments disclosed herein relate to structures and methods for electron-hole photogeneration, and in particular to plasmonic multiple exciton generation.

### BACKGROUND

There is a small number of concepts known that can enable a single junction photovoltaic device to provide solar power conversion efficiency above the Shockley-Queisser limit of ˜32% (series stacked, or multijunction, cells can provide up to 45% efficiency, but these are prohibitively expensive and so, as yet, not scalable). These concepts are (1) hot electrons, where one expects will provide higher open circuit voltage compared to conventional PV cells, (2) multiple exciton generation (MEG), where one expects will provide higher closed circuit current compared to conventional PV cells, and (3) the many related phenomena associated with the so-called anomalous PV effect, also referred to as the bulk PV effect, where again the open circuit voltage to be higher than that of conventional PV cells.

To date, the state of the art in MEG solar cells involves an assembly of quantum-confined semiconductor media (“quantum dots”, QDs) acting as solar absorbers, embedded in an insulating (or high band gap) material. Under proper conditions, a single high energy (well above semiconductor band gap Eg) photon with energy Ep is absorbed by a QD. Instead of exciting a single electron-hole pair, however, a phenomenon of inverse photoemission can occur within the QD, and the excess energy above the gap (Ep−Eg) is “reused” to generate additional electron-hole pair or pairs. For example, if Ep>2 Eg, up to two pairs can be created; if Ep>3 Eg, up to three, etc. By this process, multiple electron-hole pairs (excitons) can be created by a single incident photon. If these pairs can be extracted by the conventional diode/rectifier effect, it stands to reason that additional current, beyond that attainable in the conventional single-junction PV effect, can be realized.

Such excess current has not been so realized to date. One reason is that for a photo-excited electron or hole to migrate out of the QD from which is was excited to the sample edge, and thus contribute to measurable current, it must “hop” from one QD to the next until it reaches the edge. This hopping can only take place by a process of quantum tunneling—in fact, many consecutive quantum tunnelings to move a macroscopic distance to the sample edge. Quantum tunneling is a probabilistic event and, with a typical QD diameter of under 10 nm and a typical thin film PV cell thickness of 100 to 500 nm, many tunneling events are required. For example, if the tunneling probability is 99% for a QD size of 5 nm and a QD-to-QD spacing gap of 1 nm, the probability of a charge carrier counting for current is between 43% and 85%. If the tunneling probability is 90%, the current probability is, at most, between 0 and 17%. One may think to increase the tunneling probability by positioning the QDs closer to each other (i.e. closer than the 1 nm gap in the example), thus lowering the quantum tunneling potential barrier height. Alternatively, one can envision reducing the band gap of the matrix, and thereby reducing the tunneling barrier height. However, in both cases, this has the more significant effect of quenching quantum confinement, and thus quantum tunneling, altogether. In this sense, a “quantum dot MEG solar cell” is oxymoronic: a QD can facilitate the MEG phenomenon internal the QD, but decreasing the spacing between QDs to facilitate efficient charge carrier transport kills the QD effect.

FIG. 1A is a schematic of a semiconductor energy band gap separating the lower, filled valence band from the upper, empty conduction band. It also shows two examples of the core physics of the photovoltaic effect: photoexcitation of an electron from the valence band to the conduction band, leaving behind a hole in the valence band. Lower energy light (dashed oscillating line, to indicate light at the low energy, red end of the visible spectrum) can excite an electron to just above the gap, while higher energy light, of energy Ep (solid oscillating line, to indicate light at the high energy, blue end of the visible spectrum) can excite an electron to or well above the gap, the latter yielding a hot electron and hole, at energy levels indicated by horizontal dashed lines. In this manner, a hot electron generated inside a semiconductor is an electron excited from the valence band into an energy level in the conduction band that is outside the equilibrium electron distribution at a given lattice temperature. The hot electron's free energy is typically irreversibly lost to ultrafast phonon emission (i.e., heat) as it makes its way to the bottom of the conduction band. That is, the hot, high energy electron rapidly loses its excess energy (above the conduction band minimum energy Ec) and lowers its energy to the bottom of the conduction band, as depicted in FIG. 1A, where it can be extracted as photovoltaic current. Hot electrons in general have been studied for more than half a century, as well as utilized in a variety of electronic devices, from Gunn diodes to IC diagnostics.

As mentioned, one of the seminal concepts proposed for next-generation solar PV involves harvesting the excess energy of these hot electrons before it is dissipated as heat, with theoretical efficiency limits of over 60%. This is posited to be achievable by first somehow eliminating the phonon scattering in the active region, and then extracting the hot electrons through narrow band energy filters at absorber-electrode contacts, assuring isentropic cooling. However, this is far from a trivial proposition, and no successful solar cell based on this idea has been developed. While early investigations found some evidence for hot electron injection into an electrolyte, there remains limited experimental evidence of improved photovoltaic performance via hot electrons, despite many decades of research.

Another seminal concept proposed for next-generation solar PV, MEG, involves the high energy photon generating, rather than a hot electron high into the conduction band, more than one electron-hole pair, each with energy just greater than the band gap Eg. One example of the MEG concept is depicted in FIG. 1B: a high energy photon with energy greater than or equal to 3Eg (solid oscillating line in FIG. 1B) excites not one but three electron-hole pairs. In an idealized case, this process would lead to 3 times as much current as the case of a photon with the same energy in the absence of MEG, as in FIG. 1A.

### SUMMARY

In accordance with one aspect of the present disclosure, there is provided a metamaterial structure including a light absorbing layer including a semiconducting medium having a plurality of plasmonic metal nanoparticles dispersed therein, wherein the plurality of plasmonic metal nanoparticles are spaced apart at a distance sufficient to create overlapping plasmons of adjacent plasmonic metal nanoparticles when incident light strikes the nanoparticles such that plasmonic multiple exciton generation is achieved.

In accordance with another aspect of the present disclosure, there is provided a photovoltaic cell including top and bottom electrodes disposed on the top and bottom surfaces of the light absorbing layer of the present disclosure, the top and bottom electrodes in electrical communication with the light absorbing layer so as to collect electrical current generated in the light absorbing layer.

In accordance with another aspect of the present disclosure, there is provided a method for plasmonic multiple exciton generation in a solar cell including: dispersing a plurality of plasmonic metal nanoparticles in the semiconducting medium of a light absorbing layer, wherein the plasmonic metal nanoparticles are spaced apart at a distance sufficient to create overlapping plasmons of adjacent plasmonic metal nanoparticles when incident light strikes the nanoparticles; and collecting electrical current generated in the light absorbing layer by a top electrode disposed on the light absorbing surface of the light absorbing layer and a bottom electrode disposed on the surface of the absorbing layer opposite to the light absorbing surface of the light absorbing layer, wherein the light absorbing layer absorbs solar energy and converts the absorbed energy into electrical current by plasmonic multiple exciton generation.

These and other aspects of the present disclosure will become apparent upon a review of the following detailed description and the claims appended thereto.

### BRIEF DESCRIPTION OF THE DRAWINGS

FIG. 1A is a schematic of a semiconductor band gap in a conventional solar cell, and the conventional excitation of a single electron-hole pair per photon and FIG. 1B is a schematic of a semiconductor band gap in an MEG solar cell, and the excitation of a multiple (three as an example) electron-hole pairs per high (energy >3Eg) energy photon;

FIG. 2A is a diagram schematically showing multiple exciton generation in a quantum dot-based solar cell, and conventional tunneling events of electrons and holes between semiconductor quantum dots, separated by an insulating medium, as they migrate to their respective contacts (i.e. top electron contact and bottom hole contact), and FIG. 2B is a diagram schematically showing plasmonic multiple exciton generation in an PV absorber in the regions of plasmonic fields emanating from metallic nanoparticles, with plasmonic-generated electrons and holes migrating to their respective contacts without undergoing tunneling events, in accordance with an embodiment of the present disclosure;

FIG. 3 is a graph of the hot electron population in crystalline silicon immediately after photoexcitation;

FIG. 4 illustrates an energy flow diagram;

FIG. 5 depicts relative (per unit volume of the absorber) absorption spectra of GaAs absorber filled with cubic array of Ag NPs (period a, diameter D=a/3). Strong plasmonic absorbance is seen around 400 THz. Inset shows basic PMEG scheme: incident high energy photon (dark blue) interacts with NP to establishes a surface plasmon, whose strong E-field (gradient blue) excites a bi-exciton, which separates into two electron-hole pairs, which drift/diffuse via an inferred p-n junction. Top axis shows relevant energy and wavelength scales;

FIG. 6 depicts extracted effective dielectric function of the GaAs absorber filled with a cubic array of Ag nanospheres (each with diameter D=a/3) for two nanosphere sizes D=6.7 nm (black), and D=67 nm (red). The inset shows the corresponding electron-electron scattering rates. The shaded area represents the rates of electron-phonon scattering processes;

FIG. 7 depicts calculated electron-electron scattering rates for a crystalline Si absorber filled with a cubic array of Ag nanospheres (of diameter D=a/3), with a=200 nm (black curve) and a=230 nm (red curve). The inset shows the corresponding extracted effective dielectric functions, used to obtain the scattering rates;

FIG. 8 depicts calculated electron-electron scattering rates for a Ge absorber filled with a cubic array of Ag nanospheres (each with diameter D=a/3=33.3 nm). The inset shows the corresponding extracted effective dielectric function, used to obtain the scattering rates; and

FIG. 9 illustrates an embodiment of a solar cell including a NP-impregnated PV absorber structure in accordance with an embodiment of the present disclosure.

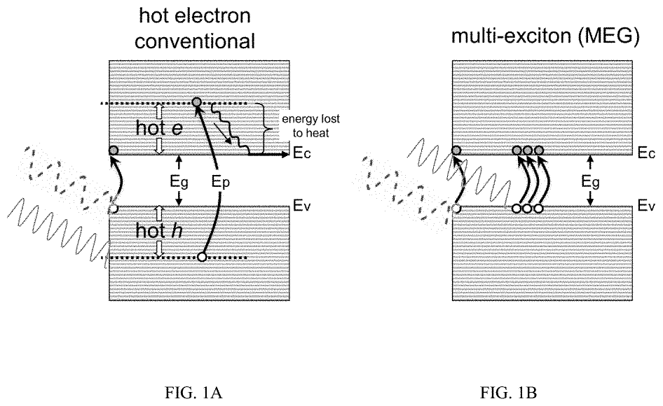

### DETAILED DESCRIPTION

The present disclosure achieves multiple electron-hole photogeneration without the use of QDs and the internal contradictions associated therewith. Instead of a conventional insulating matrix impregnated with a plurality of nanosized semiconducting, light-absorbing QDs, the present disclosure contains a semiconducting, light-absorbing medium impregnated with a plurality of nanosized, plasmonic metal nanoparticles (NPs). Such NPs can be composed of bare metal, or metal coated with a dielectric (core-shell configuration). The NPs can have various sizes and shapes, including spheres ranging in diameter from about 3 nm to about 50 nm. Other suitable shapes include, e.g., triangles/pyramids, cubes, stars, icosohedra, dodecahedra, and the like, with spatially-averaged dimensions of from about 3 nm to about 50 nm. These NPs are spaced apart at a distance sufficient to create overlapping plasmon-induced electromagnetic fields when struck by incident light, such that plasmonic multiple exciton generation is achieved in the semiconducting medium. Plasmons within and/or on the surfaces of the NPs are formed by (excited by) incident light, creating intense electric fields within the near electromagnetic field of the NP surfaces (i.e. within a distance of approximately one wavelength of the incident (free-space) light, scaled to the refractive index n of the absorbing medium, surrounding the NPs). For example, with silicon (n=3.4) as the semiconducting absorbing medium, incident light of free-space wavelength 500 nm creates a plasmon extending from the surface of the NP to a distance of 500 nm/3.4˜150 nm from the surface of the NP. Therefore, an embodiment wherein a plurality of NPs are disposed in the matrix at a distance within two so-scaled wavelengths of the incident light to adjacent NPs results in neighboring NPs having overlapping plasmon fields. The strong electric field (E-field) associated with the excited plasmons in this electromagnetic field facilitates multiple electron-hole pair creation in the semiconducting matrix. In this situation, the photoexcited pairs can traverse the sample in the typical manner of a conventional PV solar cell (i.e. without the need to hop or tunnel), and be harvested as electric current. In an embodiment, this disclosure allows for an upgrade modification of any existing PV device, so long as a scheme is provided to distribute the NPs in a given PV active volume.

This plasmonic multiple excitation generation (PMEG) concept has the potential to lead to record high PV efficiency—perhaps in excess of 50%, and displace all current PV technologies. The concept is scalable, in that it does not require the use of expensive crystalline materials, and can be appropriate for low-cost, scalable thin film media. For example, suitable matrix materials include amorphous silicon (a-Si), amorphous silicon-germanium (a-SiGe), cadmium telluride (CdTe), copper indium gallium selenide (CIGS) and its variants, perovskite solar cells, organic and polymeric solar cells, and the like. Suitable nanosized plasmonic metal nanoparticles include, for example, Ag, Au, Cu, Pt, Al, Ni and the like. Suitable dielectric coatings on the NPs include, for example, silicon oxide, aluminum oxide, silicon nitride, polymeric materials, and the like.

The present PMEG concept diminishes hot electron-to-phonon losses via transfer of this hot/excess energy to plasmons in a plasmonic metamaterial structure embedded in the absorber, with the transfer to plasmons occurring on a shorter time scale than transfer to heat. That is, phonon emission is much slower than this plasmon transfer process, and subsequently one can design a route to use this stored-as-a-plasmon hot electron energy to generate additional electron-hole pairs (the MEG step described below). Thus, hot electron interactions with plasmons cause photogenerated electron-hole pairs to move to the edge of the PV matrix (i.e. of the solar cell) faster than phonon emission processes that lead to energy loss via heat. To reiterate, the excess, above-gap energy of hot electrons is used to excite plasmons, the energy within which can then generate additional electron-hole pairs before it dissipates as heat (phonons) by use of the NPs embedded in the absorber in accordance with the present disclosure. The hot energy is temporarily stored in the overlapping surface plasmons, which both increases carrier photogeneration and stores energy in localized surface plasmons because electron-to-plasmon conversion is faster than the electron-to-phonon conversion.

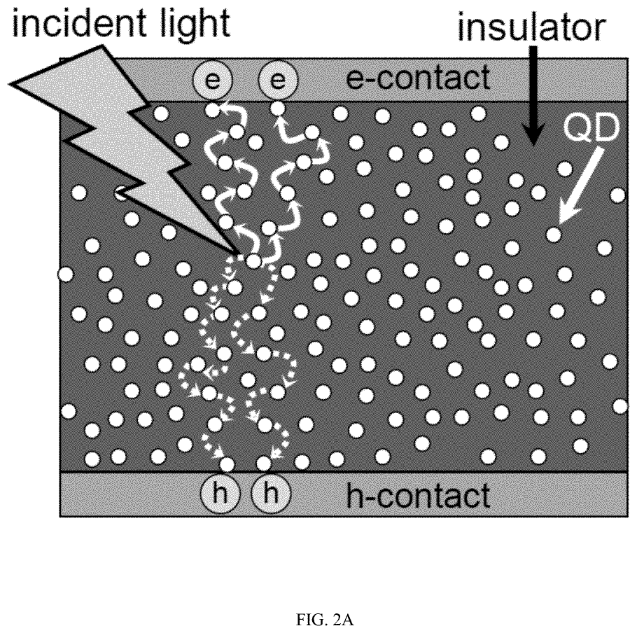

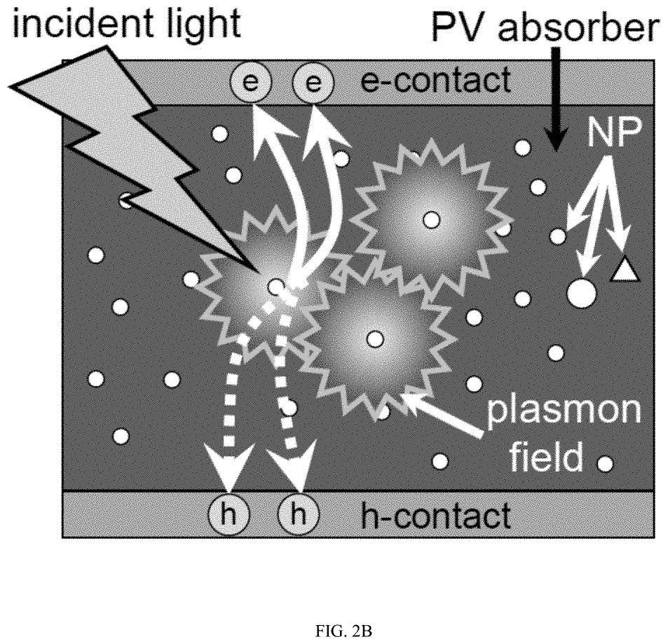

It is also important to emphasize the difference between the present PMEG and the “conventional” MEG effect. FIGS. 2A and 2B shows that difference: MEG schemes that rely on hopping and/or tunneling between semiconductor QDs, FIG. 2A, face the conundrum that as one decreases the QD spacing in order to appreciably raise the tunneling probability between dots (curved lines in FIG. 2A), that same decrease of distance suppresses or quenches the quantum confinement within the dots (by effectively increasing the size of the dots as they cluster together). In the PMEG scheme of FIG. 2B, on the other hand, the near field enhancement near the metal NPs (star-like area around a representative dot in FIG. 2B) in a surrounding semiconducting, photovoltaic absorber medium increases the generation rate of carriers into the conduction band of the semiconductor. Moreover, photoexcited electrons and holes are no longer required to hop/tunnel (as in FIG. 2A), and carrier transport is facile and continuous (curved lines in FIG. 2B).

To reiterate, quantum dots embedded in a semiconductor matrix as shown in FIG. 2A have competition between quantum confinement and dot-to-dot tunneling. Very close spacing improves tunneling between dots, but also quenches quantum confinement, reducing any potential advantageous effect of incorporating QDs, such as achieving MEG. As illustrated in FIG. 2B, on the other hand, metal NPs (with appropriate dielectric coating to suppress electron-hole surface recombination) embedded in a semiconducting PV absorber matrix enable plasmonic/near-electric-field enhancement in their vicinity (star area), which both increases carrier photogeneration in the absorber and stores hot carrier energy in localized surface plasmons. This hot energy then facilitates multiple electron-hole generation via the PMEG effect describe herein.

The MEG theory often breaks the process into two steps: first, an incoming photon excites a single exciton, with hot carriers participating; second, this exciton, before emitting phonons, decays into multiple excitons via Coulomb scattering. Instead of employing Fermi's golden rule to estimate the decay rate of excitons (hot electrons and holes) to bi-excitons, we calculate the hot electron scattering rate exactly, including secondary excitons as a part of the single particle excitation continuum. The scattering rate of an electron in a semiconductor matrix from a state Eₖ to states E_{k+q}, due to single particle and collective (plasmon) excitations (with wave vectors q), is given by

$${γ}_{el - el} = \frac{2}{ℏ} \int \frac{dq}{{( 2 π )}^{3}} {V}_{q} [ {n}_{B} ( {E}_{k} - {E}_{k + q} ) - {n}_{F} ( - {E}_{k + q} + μ ) ] Im [ {ɛ ( q , \frac{{E}_{k + q} - {E}_{k}}{ℏ} )}^{- 1} ] \qquad ( 1 )$$

where n_{B} and n_{F} are the Bose-Einstein and Fermi-Dirac distribution functions, respectively, μ is the chemical potential, ε(q,ω) is the effective longitudinal dielectric function of the medium, and V_{q} is the bare Coulomb interaction. Clearly, this calculation requires knowledge of the effective dielectric function of a given structure. In a simple, single Lorentzian approximation, the dielectric function can be written as:

$$ɛ ( ω ) = {ɛ}_{b} + \frac{{ω}_{p}^{2}}{{ω}_{r}^{2} - ω ( ω + i γ )} , \qquad ( 2 )$$

which, for γ→0⁺ and ωᵣ²>>ωₚ², when inserted into Eq. (1), leads to a simple formula:

$${γ}_{el - el} \approx \frac{\sqrt{2 {E}_{k} / m}}{2 {a}^{*}} f ( \frac{{E}_{k}}{{ℏω}_{r}} ) Θ ( \frac{{E}_{k}}{{ℏω}_{r}} - 1 ) , \qquad ( 3 )$$

where the renormalized Bohr radius is a*=a_{B}ε_{b}²(ωᵣ/ωₚ)², and the auxiliary function

$$f ( x ) = \frac{2}{x} ln ( \sqrt{x} + \sqrt{x - 1} )$$

varies slowly for x>1.5. Eq. (3) can be used as guidance for more rigorous calculations/simulations, and it shows, as expected, that the scattering vanishes for Eₖ<ℏωᵣ, and also that it increases rapidly with increasing plasmonic oscillator strength ωₚ.

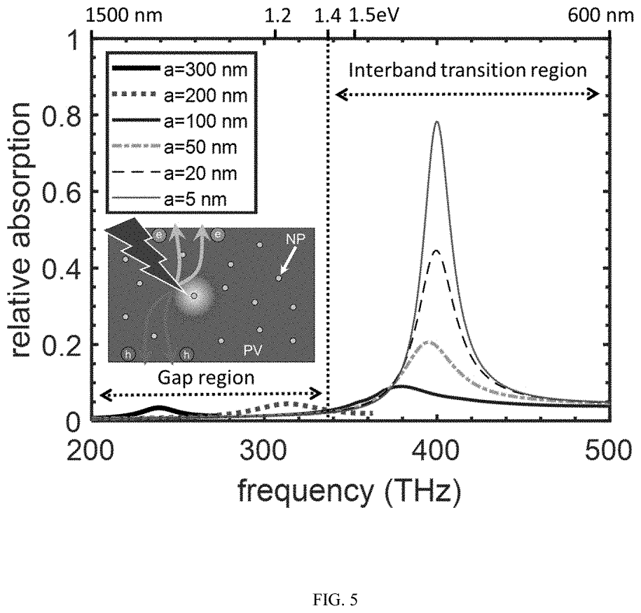

Consider now a PV absorber filled with an array of simple spherical metal NPs, as depicted in FIG. 2B and the inset to FIG. 5. If the NPs are in a cubic lattice of period a and the NP diameter is D=a/3, then the projected area fraction remains unchanged as one varies a. The relative absorption (per unit volume of the absorber), as simulated for crystalline GaAs semiconductor and Ag NPs, is shown in FIG. 5, for four values of a.

FIG. 5 shows that the frequency of the plasmonic absorption increases with decreasing a, and saturates ˜400 THz. This behavior reflects the well-known dispersion relation of a surface plasmon induced on the surface of the metallic sphere; changing the sphere diameter changes an effective surface plasmon quasi-momentum according to the “whispering gallery” mode condition q≈2/D. The plasmonic absorption peak strengths rapidly increases once the peak frequency enters the intersubband transition region above the gap energy of 1.4 eV (˜340 THz). In this region, massive generation of interband transitions (i.e. excitons) by decaying hot electrons is also expected, as will be demonstrated below. The absorption spectrum for each value of a is dominated by a single plasmonic resonance, and so one could use Eq. (2) as a simple model of the dielectric function, and then use Eq. (3) to estimate of the scattering rate. For an accurate analysis, we extract the effective dielectric function of the medium and then use the exact result from Eq. (1) to obtain the scattering rate.

In the present scheme to recover hot electron energy, it is envisioned that a single high energy photon in a solar cell will generate two or more electron-hole pairs (separated/unbound excitons), instead of or in addition to a single electron-hole pair. This is the multi-exciton generation (MEG) concept, which is conventionally known to be vanishingly small in bulk materials, in the frequency range of interest to photovoltaics.

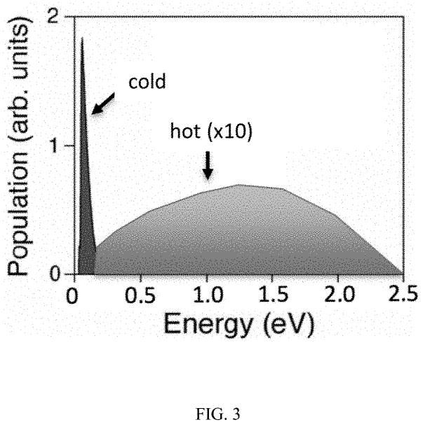

All the deficiencies associated with QD-based and other conventional MEG solar cells can be avoided by PMEG according to the present disclosure. According to an embodiment, a plasmonic structure is directly embedded in and extended throughout the absorber of a single junction solar cell, as shown schematically in FIG. 2B. This structure will have multiple functionalities. First, it is a strong plasmonic photon absorber. Second, it is an efficient hot electron energy absorber. Photoexcited hot electrons initially populate a very large portion of the conduction band. For example, as shown in FIG. 3 for crystalline Si, the population of photoexcited hot electrons (wide, shaded region, population multiplied by 10) extends from the bottom of the conduction band (Energy=0 eV on the plot) to 2.5 eV, with a maximum around 1.3 eV, while the “cold” population, while higher, is concentrated near the band edge (large peak near 0 eV). That is, FIG. 3 illustrates hot electron population in crystalline silicon immediately after photoexcitation (multiplied by 10), which cools to a final distribution within a few hundred femtoseconds (wide shaded region).

This maximum in FIG. 3 around energy 1.3 eV is very close to the band gap energy in Si (1.1 eV), meaning a photon with energy equal to at least the sum of these two numbers (i.e. 1.1+1.3 eV) has the possibility of exciting two electrons above the gap. In the current context, a plasmonic structure with plasmonic resonance tuned to this 1.3 eV energy can facilitate both efficient absorption of photons and resonant transfer of hot electron energy to the plasmon, simultaneously. Thus, upon plasmon generation on the NPs in the structure of FIG. 2B, hot electrons relax into the cold population at the bottom of the conduction band (the “cold” population in FIG. 3). In turn, the final re-absorption of plasmons by the semiconductor will cause excitation of an additional other electron from the valence band to near the bottom of the conduction band (i.e., cold). Thus, an initial single photon with e.g. energy ˜2.4 eV produces two cold electrons in the conduction band. This second generated cold electron can be viewed as due to the MEG process, but resonantly enhanced by plasmonic resonance, thus the nomenclature PMEG. Preferably, the resonance frequency (energy) of the plasmonic metal nanoparticle resonators, embedded in PV absorbers, is at or near the peak in the hot carrier distribution.

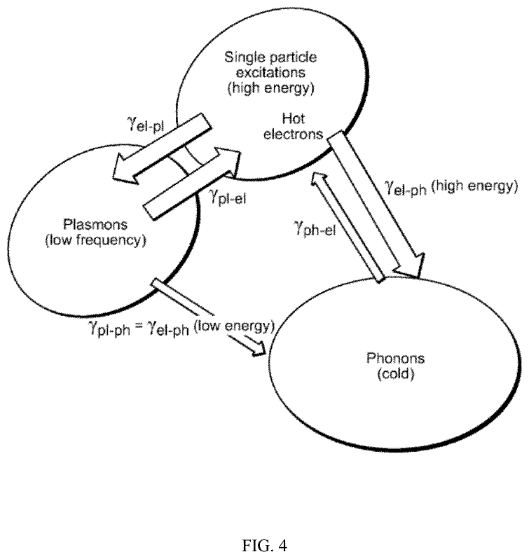

The present disclosure provides systems and methods for generating multiple electron-hole pairs via the action of plasmons. In reference to FIG. 4, the present disclosure provides plasmonic metamaterial nanostructures that can be used to reduce the electron-phonon scattering rate, by providing an alternative, fast electron-plasmon scattering channel. Because the plasmon-phonon and plasmon-photon scattering processes are relatively slow, this provides a mechanism for hot-electron plasmonic protection against phonon emission. The stored/protected energy can be returned to the single particle channel by processes similar to Rabi oscillations, and to plasmon resonance energy transfer, leading to the formation of a “plasmaron”, a coupled plasmon-electron quasiparticle. This effect could be used to control phonon scattering in various electronic systems, such as solar cells, high temperature superconductors, adjustable transition temperature superconductors, hot electron transistors, thermoelectric coolers, thermoelectric energy recovery devices, superconducting devices such as SQUIDS, and similar devices.

Hot electrons emit phonons at a rapid rate, γₑₗ₋ₚₕ (high energy). Hot electrons can also rapidly emit plasmons in a proximate plasmonic resonator with rate γₑₗ₋ₚₗ, which can be higher (faster) than γₑₗ₋ₚₕ. Because the plasmon energy can be designed to be small, the subsequent emission of phonons by the plasmons is at a slower rate: γₚₗ₋ₚₕ (low freq)=γₑₗ₋ₚₕ (low energy), which is much less than γₚₗ₋ₚₕ (high energy). Because plasmons generate hot electrons at a rate γₚₗ₋ₑₗ equal to γₑₗ₋ₚₗ, a plasmonic resonator can act to reduce phonon emission by hot electrons.

In some embodiments, the absorbing layer is capable of absorbing solar energy and converting the absorbed energy into electrical current. In some embodiments, the absorbing layer is a semiconductor or photovoltaic junction. In some embodiments, the absorbing layer is a p-n junction. In some embodiments, the absorbing layer is a p-i-n junction. In some embodiments, the absorbing layer is selected from semiconductor materials, including, without limitations, group IV semiconductor materials, such as amorphous silicon, hydrogenated amorphous silicon, crystalline silicon (e.g., microcrystalline polycrystalline, or nanocrystalline silicon), and germanium, group III-V semiconductor materials, such as gallium arsenide and indium phosphide, group II-VI semiconductor materials, such as cadmium selenide and cadmium telluride, and chalcogen semiconductor materials, such as copper indium selenide (CIS) and copper indium gallium selenide (CIGS). In some embodiments, the absorbing layer is made of a material having a refractive index greater than 3. In some embodiments, the absorbing layer is made of a material having a refractive index greater than 4.

By way of a non-limiting example, the absorbing layer is a thin photovoltaic junction of amorphous silicon (a-Si). In some embodiments, the absorbing layer is a thin p-i-n junction of amorphous silicon (a-Si). As used herein, the term “thin photovoltaic junction” refers to photovoltaic junctions or photovoltaic films (which terms may be used interchangeably throughout the instant application) having an overall junction thickness between about 1 nanometer (nm) and about 1000 nm. In some embodiments, a thin photovoltaic junction of the present disclosure has an overall junction thickness between about 10 nm and about 300 nm. In some embodiments, a thin photovoltaic junction of the present disclosure has an overall junction thickness between about 10 nm and about 40 nm. In some embodiments, a thin photovoltaic junction of the present disclosure has an overall junction thickness between about 15 nm and about 30 nm. In some embodiments, a thin photovoltaic junction of the present disclosure has an overall junction thickness of about 40 nm. In some embodiments, a thin photovoltaic junction of the present disclosure has an overall junction thickness of about 15 nm.

The disclosure will be further illustrated with reference to the following specific examples. It is understood that these examples are given by way of illustration and are not meant to limit the disclosure or the claims to follow.

### Example 1

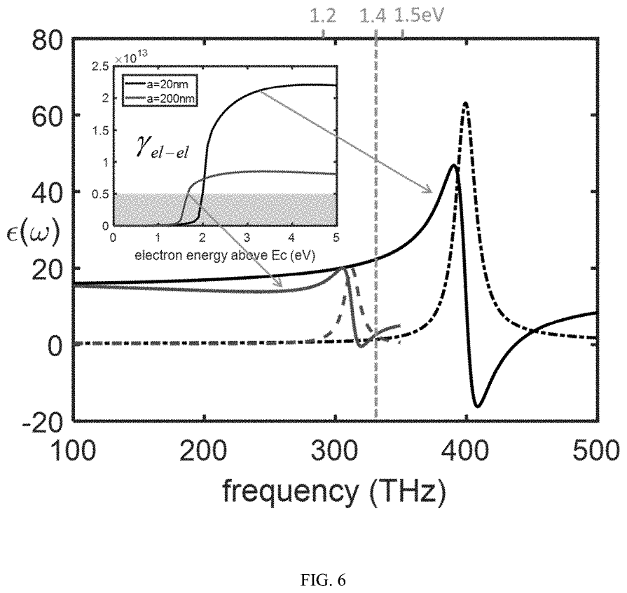

The extracted single Lorentzian dielectric functions for D=67 nm and 6.7 nm are shown in FIG. 6. The inset shows the corresponding scattering rates vs. hot electron energy. For the smaller spheres, intersubband transitions are possible (producing secondary excitons), and the scattering rates of hot electrons with energies 2.5 eV and more above the conduction band edge exceed 2×10¹³ s⁻¹ (i.e. faster than 50 ps). This rate is larger than the phonon cooling rate in GaAs of ˜0.5×10¹³ s⁻¹ (i.e. 200 ps). This is the rate at which the hot electrons cool to the bottom of the conduction band, which requires many electron-phonon scattering events; the energy of a single phonon is only ˜36 meV, such that more than 50 scattering events are needed to completely cool a hot electron with energy 2 eV. The shaded area in the inset in FIG. 6 shows an estimated cooling rate. For larger spheres (D=67 nm), with resonances below the energy gap, no secondary excitons are generated, only plasmons at a smaller rate.

As the efficiency of PMEG diminishes with increasing gap size, only hot electrons with energy greater than the gap can generate secondary excitons. In fact, GaAs is not an optimal material for PMEG solar cells. The maximum value of the hot electron energy generated by AM1.5 solar radiation (as measured from the top of the valence band) is about 3.4 eV, and so we estimate that in GaAs, the hot electrons reach only about 3.4 eV-1.4 eV=2 eV into the conduction band. However, FIG. 6 shows that significant (exceeding the phonon scattering rate) plasmon generation occurs for hot electrons with energy >2 eV, such that only a small fraction of photo-generated hot electrons can generate secondary excitons. Nevertheless, GaAs is a good material to demonstrate the PMEG effect by using laser illumination.

### Example 2

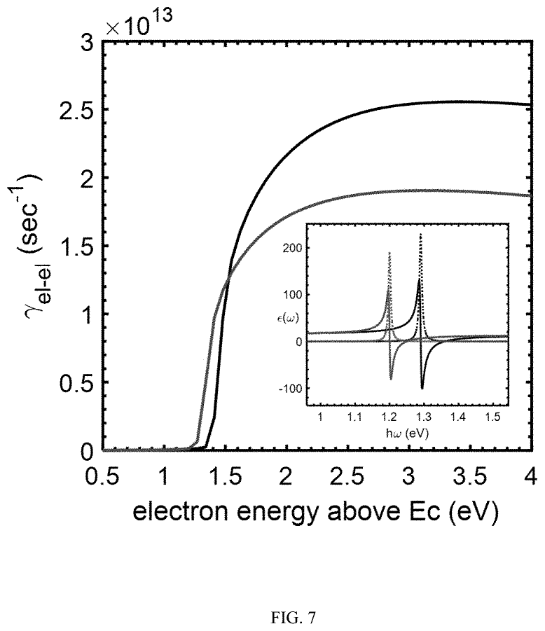

Employing the same procedure in crystalline Si as for GaAs, one obtains the result shown in FIG. 7. The scattering rates are shown in the main part of the figure, for two NP diameters, D=67 and 76 nm. In this case, the solar radiation-induced hot electron bandwidth is equal to 3.4 eV-1.1 eV=2.3 eV. For the larger diameter sphere, a significant scattering rate (˜1.5×10¹³ sec⁻¹) arises for 1.3 eV, which exceeds that of the electron-phonon cooling rate (<10¹³ sec⁻¹). Thus, in this case, a reasonably large portion of the hot electron distribution, ˜43%, is available for PMEG recovery. Thus, crystalline Si is a viable material for both PMEG demonstration and a PMEG solar cell.

### Example 3

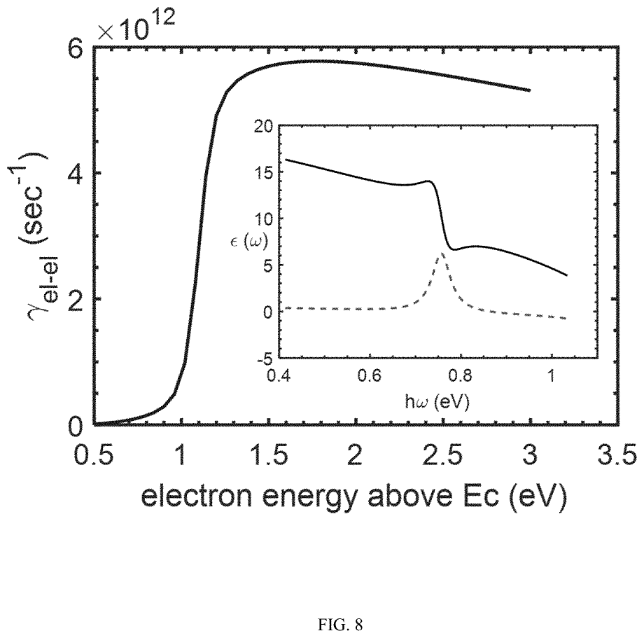

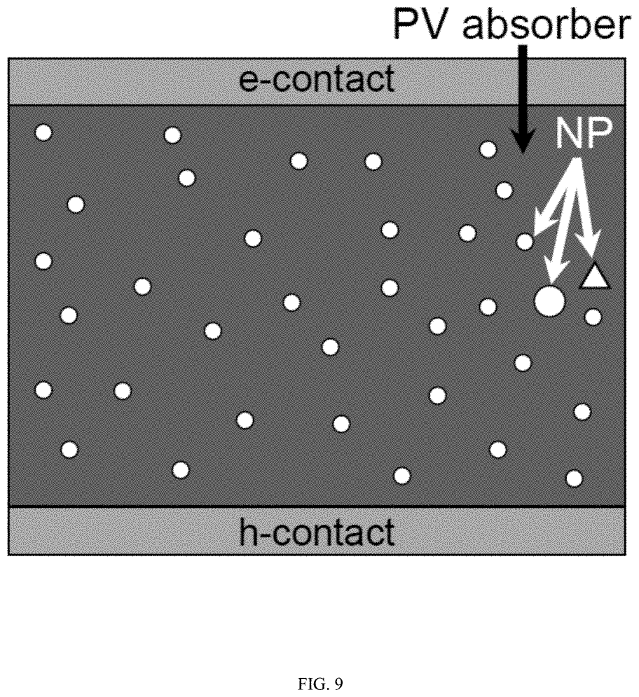

Semiconductors with even smaller gaps, such as Ge (0.68 eV) or InAs (0.32 eV), should further improve the efficiency of PMEG. As an example, we consider Ge in FIG. 8, for NPs with D=33.3 nm. The scattering rate has a maximum near 1.5 eV, representing the PMEG. Since in this case the range of hot electrons induced by a 1-sun illumination is 3.4 eV-0.7 eV=2.7 eV (as measured from the bottom of the conduction band), a large fraction of hot electrons (more than 50%), with energies ranging from 1.3 eV to 2.7 eV, can produce the secondary electrons. The electron-phonon scattering rate in Ge is ˜10¹⁴ sec⁻¹, and the corresponding cooling rate (in view of the single phonon emission energy of ˜20 meV) is ˜10¹² sec⁻¹, much lower than the electron-electron scattering rate. Thus, we can conclude that Ge could be used as a practical platform for PMEG cells.

There are other possible methods of developing arrays of NPs inside and active absorber volume. Wet chemistry-processed semiconductors is one example, as embedding can be achieved by simply mixing the NPs with the semiconductor. Embedding NPs into amorphous semiconductors processed by PECVD (a-Si and a-Ge) can be also obtained relatively easy by the layer-by-layer processing, or co-sputtering of a metal and semiconductor, followed by thermal processing. Embedding plasmonic NPs into crystalline semiconductors is much more challenging. Most promising are crystalline NPs of silicides, which are plasmonic (metallic) with plasma energies in the 3 eV range, and so similar to Ag or Au. Most importantly, silicides are nearly lattice matched to Si, so they can be epitaxially grown on Si, and vice versa. Many of the silicide NPs are also compatible with Ge, opening an avenue to PMEG solar cells. Another route is NP implantation, which allows deposition of NP growth seeds into semiconductors by ion implantation, and subsequent NP growth from those seeds during annealing, which restores crystalline structure.

Although various embodiments have been depicted and described in detail herein, it will be apparent to those skilled in the relevant art that various modifications, additions, substitutions, and the like can be made without departing from the spirit of the disclosure and these are therefore considered to be within the scope of the disclosure as defined in the claims which follow.

1. A metamaterial structure comprising:
a light absorbing layer comprising a semiconducting medium having a plurality of plasmonic metal nanoparticles dispersed therein, wherein when incident light strikes the nanoparticles achieving plasmonic multiple exciton generation, a single photon generates two or more electron-hole pairs in the semiconducting medium.

2. The metamaterial structure of claim 8, wherein the distance comprises up to two wavelengths scaled to a refractive index of the semiconducting medium of a selected wavelength of the incident light.

3. The metamaterial structure of claim 1, wherein the plurality of plasmonic metal nanoparticles comprises at least two different sizes.

4. The metamaterial structure of claim 1, wherein the plurality of plasmonic metal nanoparticles comprises at least two different shapes.

5. A photovoltaic cell comprising:
top and bottom electrodes disposed on the top and bottom surfaces of the light absorbing layer of claim 1, the top and bottom electrodes in electrical communication with the light absorbing layer so as to collect electrical current generated in the light absorbing layer.

6. A method for plasmonic multiple exciton generation in a solar cell comprising:
dispersing a plurality of plasmonic metal nanoparticles in a semiconducting medium of a light absorbing layer;
generating in the semiconducting medium two or more electron-hole pairs from a a single incident photon; and
collecting electrical current generated in the light absorbing layer by a top electrode disposed on the light absorbing surface of the light absorbing layer and a bottom electrode disposed on the surface of the absorbing layer opposite to the light absorbing surface of the light absorbing layer, wherein the light absorbing layer absorbs solar energy and converts the absorbed energy into electrical current by plasmonic multiple exciton generation.

7. The method of claim 9, wherein the distance comprises up to two wavelengths scaled to a refractive index of the semiconducting medium of a selected wavelength of the incident light.

8. The metamaterial structure of claim 1, wherein the plurality of plasmonic metal nanoparticles are spaced apart at a distance sufficient to create overlapping plasmons of adjacent plasmonic metal nanoparticles.

9. The method of claim 6, wherein the plurality of plasmonic metal nanoparticles are spaced apart at a distance sufficient to create overlapping plasmons of adjacent plasmonic metal nanoparticles.
